(19) United States
(12) Patent Application Publication
(10) Pub. No.: US 2008/0006834 A1
(43) Pub. Date: Jan. 10, 2008

(54) PANEL SUBSTRATE, DISPLAY APPARATUS AND MANUFACTURING METHOD THEREOF

(75) Inventor: Yasuo Fujita, Kumamoto (JP)

Correspondence Address: OBLON, SPIVAK, MCCLELLAND MAIER & NEUSTADT, P.C., 1940 DUKE STREET, ALEXANDRIA, VA, 22314, US

(73) Assignee: MITSUBISHI ELECTRIC CORPORATION, Tokyo (JP)

(21) Appl. No.: 11/765,727

(22) Filed: Jun. 20, 2007

(30) Foreign Application Priority Data
Jun. 23, 2006 (JP) 2006-173242

(51) Int. Cl. H01L 31/12; H01L 27/15; H01L 33/00; H01L 29/16

(52) U.S. Cl. 257/83

(57) ABSTRACT

A panel substrate includes a first mother substrate having a plurality of array substrates and a second mother substrate having a plurality of opposing substrates opposing to the array substrates. The panel substrate has a seal material for bonding the array substrates and the opposing substrates and a display material provided in a display material filled area. The first mother substrate has a line provided to the first mother substrate and an input terminal formed outside a display material filled area. The hydrophobic film is formed over the second mother substrate and placed in an opposing area having the input terminal facing the opposing substrate.

### BACKGROUND OF THE INVENTION

1. Field of the Invention

The present invention relates to a panel substrate, display apparatus and manufacturing method thereof.

2. Description of Related Art

Generally liquid crystal panels are used for liquid crystal displays, which are typical examples of display apparatuses. A thin film transistor (TFT) array substrate is provided to the liquid crystal panel. The TFT array substrate includes TFTs and pixel electrodes connected to the TFT. Moreover, a pixel area is formed by arranging the TFT and pixel electrode in matrix. Furthermore, scanning signal lines and display signal lines are formed to the TFT array substrate to be connected to the TFTs. One element segment having the plurality of scanning and display signal lines is formed to such TFT array substrate. Additionally, terminals for inputting a signal to the scanning and display signal lines are formed at the end of an element segment in the TFT array substrate.

Moreover, an opposing substrate is placed to the TFT array substrate. An opposing electrode and a resin film or the like are formed to the opposing substrate. Furthermore, the TFT array substrate and the opposing substrate are bonded using a seal material. Here, the seal material is formed to shape a frame, surrounding the pixel area. After that, liquid crystal is filed in the area formed by the TFT array substrate, opposing substrate and seal material.

If terminals and lines of the TFT array substrate are corroded, a failure in display is generated. Thus, a technique is disclosed in Japanese Unexamined Patent Application Publication No. 2003-195336 to cover wirings with a water-repellent film for corrosion prevention in order to prevent corrosion of each signal line in the TFT array substrate. In this document, after mounting a FPC with an ACF, organic solvent is sprayed to the portion where the wiring is placed and nearby area. Then the water-repellent film for corrosion prevention is formed before the coated organic solvent is vaporized. Further, another technique for preventing from corrosion is disclosed in Japanese Unexamined Patent Application Publication No. H10-187054. In this document, UV resin is formed to the end of the substrate in the portion where cross-section of the wiring pattern is exposed after a cutting process.

Incidentally, in a manufacturing process of a liquid crystal panel, several TFT array substrates and opposing substrates are usually obtained by cutting a large-sized mother substrate in light of mass productivity. Specifically, a plurality of the above mentioned TFT array substrates or opposing substrates are arranged in vertical and horizontal directions on mother substrates. Then the mother substrate having the plurality of TFT array substrates and the mother substrate having the plurality of opposing substrates are bonded with a seal material interposed therebetween. Then after bonding with the seal material, the mother substrates are divided so that the plurality of element segments are aligned in one line. Specifically, the mother substrates are divided so that a plurality of liquid crystal cells are aligned in one line. By cutting the mother substrate in this way, a stick substrate is formed. A method for filling liquid crystal to a plurality of liquid crystal cells at once afterward is disclosed in Japanese Unexamined Patent Application Publication No. 2004-317982.

Incidentally, the abovementioned opposing electrode is usually formed to almost the entire surface of the opposing substrate. Thus after the bonding process, the opposing electrode may face the terminals of the TFT array substrate outside the seal material. Here, a cell gap is 5 μm, extremely narrow. Before connecting a driving circuit etc., terminals for the wiring of the TFT array substrate are exposed. Moreover, these terminals may face the opposing electrode of the opposing substrate.

When carrying out a lighting test on a liquid crystal panel, a probe needle or the like is brought into contact with a test terminal for example. Then a signal is supplied to a line from the probe needle or the like via the test terminal. This applies a voltage between the opposing electrode and the line. Then a test is conducted for whether or not the lighting can be successfully performed. In order to improve productivity, this test is sometimes conducted at a state of stick substrate.

At the state of stick substrate, a water droplet sometimes immerses in the narrow cell gap between the opposing substrate and TFT array substrate in a cleansing process or by moisture condensation. When applying different voltages between the terminal and opposing electrode or between terminals with the water droplet attached to terminals, an electrochemical reaction may be generated between the terminal and opposing substrate or between terminals. There is a problem that due to this electrochemical reaction, the terminals corrodes and this causes a display failure in a liquid crystal display. However in Japanese Unexamined Patent Application Publication No. 2003-195336, as the water-repellent film for corrosion prevention or the like is formed after forming a liquid crystal panel, corrosion in test process cannot be prevented. Furthermore in Japanese Unexamined Patent Application Publication No. H10-187054, a protection film is formed to a cut section of a line. Thus corrosion of a terminal cannot be prevented. As described above, in these techniques, corrosion may be created in terminals by the voltage applied in the test process. Accordingly in a conventional liquid crystal display, there is a problem that display quality is deteriorated. Such problem could be generated not only in a liquid crystal display but in a display apparatus using a display material other than liquid crystals. For example a similar problem is generated in an electronic paper or the like having a TFT array substrate bonded with an opposing substrate.

The present invention seeks to solve the abovementioned problems or to improve upon those problems at least in part and aims to provide a panel substrate, display apparatus and manufacturing method thereof.

### SUMMARY OF THE INVENTION

According to an aspect of the present invention, there is provided a panel substrate that includes a first mother substrate having a plurality of array substrates, a second mother substrate having a plurality of opposing substrates opposing to the array substrates, a seal material for bonding the array substrates and the opposing substrates, a display material provided in a space formed by the array substrates, the opposing substrates and the seal material, a line provided to the first mother substrate, an input terminal formed outside a display material filled area in the array substrate for inputting a signal to the line, the display material filled area having the display material being filled therein and a hydrophobic film formed over the second mother substrate and placed in an opposing area having the input terminal facing the opposing substrate.

According to a second aspect of the present invention, there is provided a display apparatus that includes an array substrate, an opposing substrate placed opposing the array substrate, a seal material for bonding the array substrate and the opposing substrate, a display material provided in a space formed by the array substrate, the opposing substrate and the seal material, a line provided over the array substrate, an input terminal formed outside the seal material of the array substrate for inputting a signal in the line and a hydrophobic film formed over the array substrate and provided closer to the array substrate end than the input terminal.

According to a third aspect of the present invention, there is provided a method of manufacturing a display apparatus having an array substrate with an input terminal for inputting a signal to a line and an opposing substrate from a first mother substrate having a plurality of the array substrates and a second mother substrate having a plurality of opposing substrates. The method includes forming a hydrophobic film near the input terminal over the first mother substrate, bonding the first mother substrate with the second mother substrate with a seal material interposed therebetween so that the hydrophobic film formed to the first mother substrate faces the opposing substrate, filling a display material in a space formed by the seal material, the opposing substrate and the array substrate, inputting a signal to the line in order to perform a test process at a state in which the hydrophobic film faces the input terminal outside a display material filled area having the display material filled therein and dividing into a display panel having one opposing substrate and one array substrate after the test process.

According to a fourth aspect of the present invention, there is provided a method of manufacturing a display apparatus having an array substrate with an input terminal for inputting a signal to a line and an opposing substrate from a first mother substrate having a plurality of the array substrates and a second mother substrate having a plurality of opposing substrates. The method includes forming a hydrophobic film over the opposing substrate of the second mother substrate, bonding the first mother substrate with the second mother substrate with a seal material interposed therebetween so that the hydrophobic film formed to the second mother substrate faces the input terminal, filling a display material in a space formed by the seal material, the opposing substrate and the array substrate, inputting a signal to the line in order to perform a test process at a state in which the hydrophobic film faces the input terminal outside a display material filled area having the display material filled therein and dividing into a display panel having one opposing substrate and one array substrate after the test process.

The present invention provides a panel substrate, display apparatus and manufacturing method thereof for preventing to deteriorate display quality.

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

FIG. 1 is a plan view showing the configuration of a mother substrate of a TFT array substrate;

FIG. 2 is a plan view schematically showing the configuration of the TFT array substrate;

FIG. 3 is a plan view showing the configuration of a mother substrate of an opposing substrate;

FIG. 4 is a plan view schematically showing a pixel configuration of an opposing substrate;

FIG. 5 is a cross-section diagram taken along the line V-V of FIG. 4;

FIG. 6 is a perspective view showing the configuration of a stick substrate;

FIG. 7 is a plan view schematically showing the configuration of a stick shaped array substrate;

FIG. 8 is a cross-section diagram showing the configuration of a stick substrate;

FIG. 9 shows a contact angle and rising distance of water surface;

FIG. 10 is a cross-section diagram showing another configuration of the stick substrate according to the first embodiment;

FIG. 11 shows another configuration of the stick substrate according to the first embodiment;

FIG. 12 schematically shows the configuration between the element segments of stick substrate according to a second embodiment; and

FIG. 13 schematically shows another configuration between the element segments of stick substrate according to a second embodiment.

### DESCRIPTION OF THE PREFERRED EMBODIMENTS

Hereinafter, embodiments incorporating the present invention is described with an example of a liquid crystal display with a display material of liquid crystal. In the drawings and explanation hereinafter are appropriately omitted and simplified. Further, components identical are denoted by reference numerals identical to those therein with detailed description omitted as necessary.

### First Embodiment

A liquid crystal display of this embodiment is described herein after in detail. A liquid crystal display usually includes an array substrate and an opposing substrate. Furthermore, the array substrate and opposing substrate are bonded by a frame shaped seal material. Liquid crystal is filled in an area formed by the array substrate, opposing substrate and seal material. Note that in this embodiment, the array substrate is explained as a TFT array substrate having TFTs arranged in array. That is, the liquid crystal display of this embodiment is an active matrix liquid crystal display.

Several TFT array substrates and opposing substrates are obtained by cutting a pair of mother substrates in light of mass productivity. Specifically, a mother substrate having a plurality of TFT array substrates and a mother substrate having a plurality of opposing substrates are bonded. Then the bonded substrates are cut in row or column direction to form stick substrates. Furthermore, in this embodiment, a lighting test is performed to the stick substrate having a plurality of liquid crystal panels arranged in one line. Moreover, after the lighting test is performed, the stick substrate is cut into each of the liquid crystal panel.

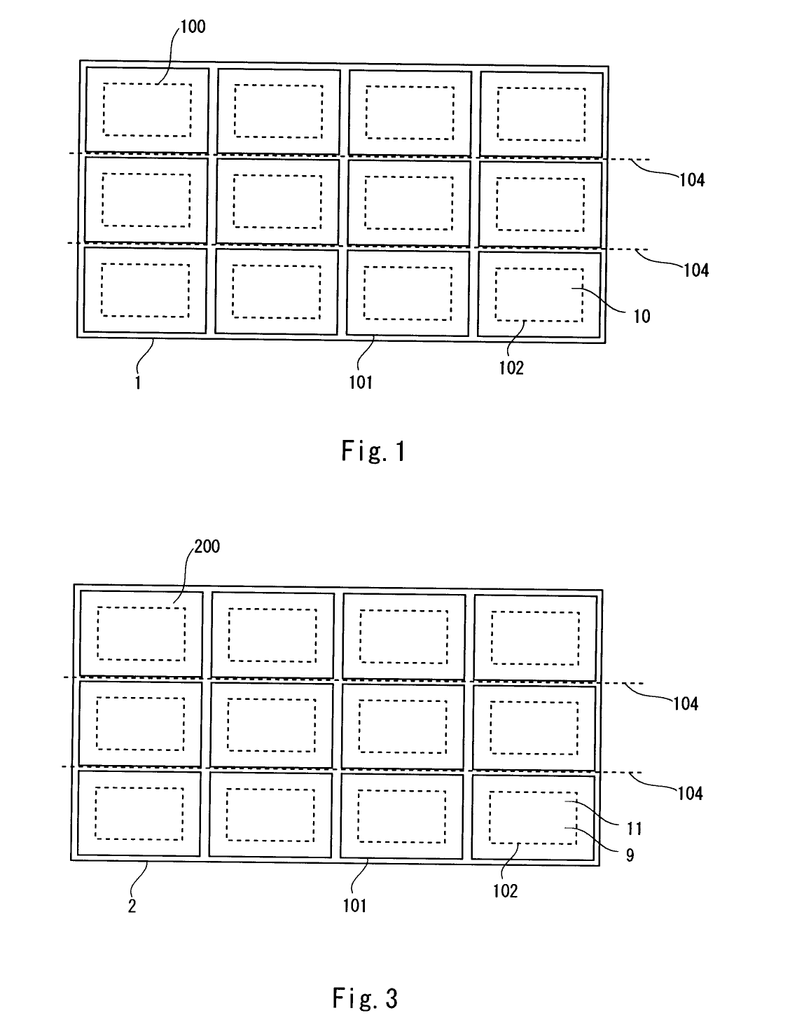

Firstly the mother substrate having the plurality of TFT array substrates is described with reference to FIG. 1. FIG. 1 is a plan view showing the configuration of a mother substrate for TFT array substrates. 3×4 TFT array substrates 100 are formed to the mother substrate 1, which is a first mother substrate. Specifically, one mother substrate 1 includes 12 TFT array substrates 100. In other words, 12 TFT array substrates 100 can be obtained by cutting the mother substrate 1 in row and column directions. The TFT array substrates 100 are formed to shape rectangles. Needless to say that the number of the TFT array substrates 100 in one mother substrate 1 is not limited to this. Here, an area for forming one liquid crystal panel is referred to as an element segment 101. Therefore, one element segment corresponds to one TFT array substrate 100. Further, in the rectangle element segment 101, lines and terminals or the like are formed to form TFT arrays.

Each of the element segments 101 is arranged with predetermined spacing. Furthermore, cutting lines 104 are placed between each of the element segments 101. That is, by cutting the mother substrate 1 along the cutting line 104, the mother substrate 1 is separated into each TFT array substrate 100. Note that in FIG. 1, only the cutting lines 104 for forming stick substrates having 4 TFT array substrates 100 are illustrated. Specifically, in fact, in addition to the cutting lines 104 in horizontal direction illustrated in FIG. 1, cutting lines in vertical direction are placed. In each of the TFT array substrates 100, a liquid crystal filled area 102 is placed. The liquid crystal filled area 102 corresponds to the display area having pixels arranged. The liquid crystal filled area 102 is surrounded by a seal material described later in detail. Moreover, in the liquid crystal filled area 102, an alignment film 10 is formed. The alignment film 10 is formed over the surface of the TFT array substrate 100. Further, outside the display area of the TFT array substrate 100 is a frame area.

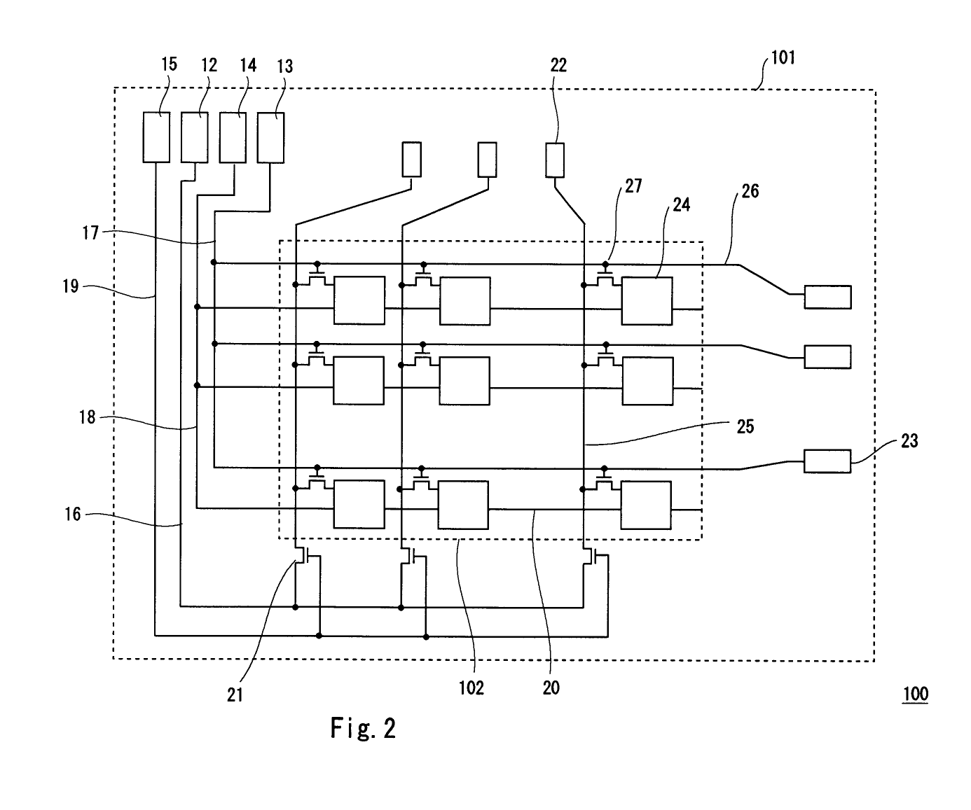

Next, the configuration of the TFT array substrate 100 is described with reference to FIG. 2. FIG. 2 is a plan view schematically showing the configuration of the TFT array substrate 100. The configuration of the TFT array substrate 100 is described hereinafter in order of manufacturing process. For the TFT array substrate 100, a transparent glass substrate can be used, for example. A plurality of gate lines and a plurality of storage capacity lines 20 made of metal such as Al and Cr or the like are formed to the TFT array substrate 100. The plurality of gate line 26 are formed in parallel. Furthermore, the storage capacity lines 20 are placed between the adjacent gate lines 26. A gate insulating film (not shown) and semiconductor layer (not shown) are sequentially formed over the gate lines 26 and storage capacity lines 20. By a known CVD, the gate insulating film and semiconductor layer can be deposited. The gate insulating film is a transparent insulating film of a silicon oxide film and silicon nitride film, for example. The semiconductor layer is for example an a-Si or p-Si layer. The gate insulating film is formed to cover the gate lines 26. The semiconductor film is formed to the place to be TFTs 27.

Moreover, a plurality of source lines 25 made of metal such as Al and Cr or the like, source electrodes and drain electrodes are formed over the gate insulating film and semiconductor layer. The plurality of source lines 25 are provided to be orthogonal to the plurality of gate lines 26 with the gate insulating film interposed therebetween. The plurality of source lines 25 are formed in parallel. By this, the TFTs 27, which are switching devices, are formed near the intersections of the gate lines 26 and source lines 25. Source electrodes of the TFT 27 are connected with the source lines 25. An interlayer insulating film is formed over the source lines 25. Furthermore, pixel electrodes 24 are formed over the interlayer insulating film. Drain electrodes of the TFTs 27 are connected with the pixel electrodes 24. The pixel electrodes 24 are connected with the drain electrodes via contact holes provided to the interlayer insulating film, for example. A gate signal for turning the TFT ON/OFF is input to the gate lines 26. A source signal corresponding to a display signal voltage is input to the source lines 25.

The abovementioned pixel electrodes 24 are arranged in matrix. For the pixel electrode 24, usually transparent conductive film such as ITO is used. As for a reflective or semi-transparent liquid crystal display, a metallic material having high optical reflectance such as Al is used for the pixel electrodes 24. The areas where the pixel electrodes 24 are provided are to be pixels. The area where these pixels are formed in matrix is to be the display area. Moreover, the pixels are formed in the liquid crystal filled areas 102. Accordingly, the liquid crystal filled area 102 is placed to surround the display area. The storage capacity lines 20 are formed below the pixel electrodes 24. The gate insulating film and interlayer insulating film are formed between the pixel electrodes 24 and storage capacity lines 20. The pixel electrodes 24 and storage capacity lines 20 are placed opposite each other with the insulating films interposed therebetween. Capacitors are formed by the pixel electrodes 24 and storage capacity lines 20. The storage capacity lines 20 are connected with opposing electrodes provided to the opposing substrate via transfer electrodes. Therefore, the pixel electrodes 24 and storage capacity lines 20 form storage capacities so as to improve data retention properties. This enables to retain the display signal voltage held in the pixel electrodes even when the TFTs 27 are turned off and a driving voltage is not supplied. More specifically, even after the TFTs 27 are turned off, the display signal voltage supplied to the pixel electrodes 24 while the TFTs 27 were on can be retained.

Additionally, test lines 16 to 19 are formed over the TFT array substrate 100. The test line 17 is connected with the plurality of gate lines 26. The test line 19 is connected with a plurality of switch devices 21. The test line 18 is connected with the plurality of storage capacity lines 20. The test line 16 is connected with the plurality of source lines 25 via the switch devices 21. The test line 19 is connected with control terminals of the switch devices 21. The test lines 16 to 19 can be formed by the same process as the gate lines 26 and source lines 25. These test lines 16 to 19 are placed outside the display area.

Gate terminals 23 are formed at the end of the gate lines 26. Here, the gate terminals 23 are placed at the right end part of the TFT array substrate 100. Moreover, the gate terminals 23 corresponding to the number of gate lines 26 are arranged in a vertical line. Likewise, source terminals 22 are formed at the end of the source lines 25. Here, the source terminals 22 are placed at the upper end part of the TFT array substrate 100. Moreover, the source terminals 22 corresponding to the number of source lines 25 are arranged in a horizontal line. Test terminals 12 to 15 are formed respectively to the end of the test lines 16 to 19. Here, the test terminals 12 to 15 are formed to the upper end part of the TFT array substrate 100. Further, the test terminals 12 to 15 are placed to the left side of the source terminals 22. The same conductive layer as the pixel electrodes 24 is formed to the surface of the source terminal 22, gate terminal 23 and test terminals 12 to 15. That is, the conductive layer is exposed to the surface of the source terminals 22, gate terminals 23 and test terminals 12 to 15. This enables to input a signal from outside. The source terminals 22, gate terminals 23 and test terminals 12 to 15 are formed outside the liquid crystal filled area 102. Furthermore in FIG. 1, the source terminals 22 and test terminals 12 to 15 are arranged in line to the upper end part of the TFT array substrate 100.

The switch devices 21 are formed to the opposite end part of the source terminals 22 for the source lines 25. The switch devices 21 are thin film transistors and can be formed by the same process as the TFTs 27. The test line 17 is connected with the gate line 26 at the opposite end part of the gate terminal 23 for the gate lines 26. The test line 18 is connected with each capacity storage line 20 at an end of the storage capacity line 20.

The source terminals 22, gate terminals 23 and test terminals 12 to 15 that are formed over the TFT array substrate 100 are input terminals for inputting a signal. Specifically, a source signal is input to the source terminals 22 from a driving circuit. Furthermore, a gate signal is input to the gate terminals 23 from the driving circuit. Therefore, a source signal is supplied to the source lines 25 via the source terminals 22, and a gate signal is supplied to the gate lines 26 via the gate terminals 23. Various test signals are input to the test terminals 12 to 15 for performing a lighting test during manufacturing process.

To be more specific, a test signal for turning the switch devices 21 on is input to the test terminal 15. This enables a test signal for lighting test that is input to the test line 19 to be supplied to the source lines 25 via the switching devices 21. Test signals are input to the gate lines 26 and storage capacity lines 20 respectively via the test terminals 13 and 14. This enables to supply the test signals to the TFTs 27 and pixel electrodes 24. Furthermore, planar light source are placed to the back of the element segments 101. Thus the lighting test can be carried out. Note that at a normal time when the lighting test is not performed, the switching devices 21 are off. That is, in order to display, a source signal is input to the source line 25 from the source terminal 22.

The configuration described above is formed inside the element segment 101. These components can be formed by a known film forming method and lithography method or the like. Moreover, over the TFT array substrate 100, the abovementioned alignment film 10 is formed to cover all the pixel electrodes 24. For the alignment film 10, a resin film such as polyimide can be used. The surface of the alignment film is rubbed in a predetermined direction.

The configuration of the mother substrate having the plurality of opposing substrates is described hereinafter with reference to FIG. 3. FIG. 3 is a plan view showing the configuration of a mother substrate 2 for opposing substrates. The mother substrate 2, which is a second mother substrate, is almost same size as the mother substrate 1. Furthermore, as with FIG. 1, 3×4 opposing substrates 200 are formed to the mother substrate 2. Specifically, the mother substrate 2 includes 12 rectangle opposing substrates 200. Thus 12 element segments 101 are arranged in matrix to the mother substrate 2.

Each of the element segments 101 is arranged with predetermined spacing. Additionally, cutting lines 104 are placed between each of the element segments 101. That is, by cutting the mother substrate 2 along the cutting line 104, the mother substrate 2 is separated into each opposing substrate 200. Note that also in FIG. 2 as with FIG. 1, only the cutting lines 104 for forming stick substrates having 4 opposing substrates 100 are illustrated. The cutting lines 104 are placed so that the opposing substrate 200 is slightly smaller than the TFT array substrate 100. The opposing substrate 200 is cut to be slightly smaller than the TFT array substrate 100. This enables to expose the source terminals 22, gate terminals 23 and test terminals 12 to 15 that are provided to the TFT array substrate 100. Moreover, as with the mother substrate 1, the liquid crystal filled area 102 is formed in each of the element segment 101. In the liquid crystal filled area 102, an alignment film 9 is provided. The alignment film 9 is formed over the surface of the opposing substrates 200.

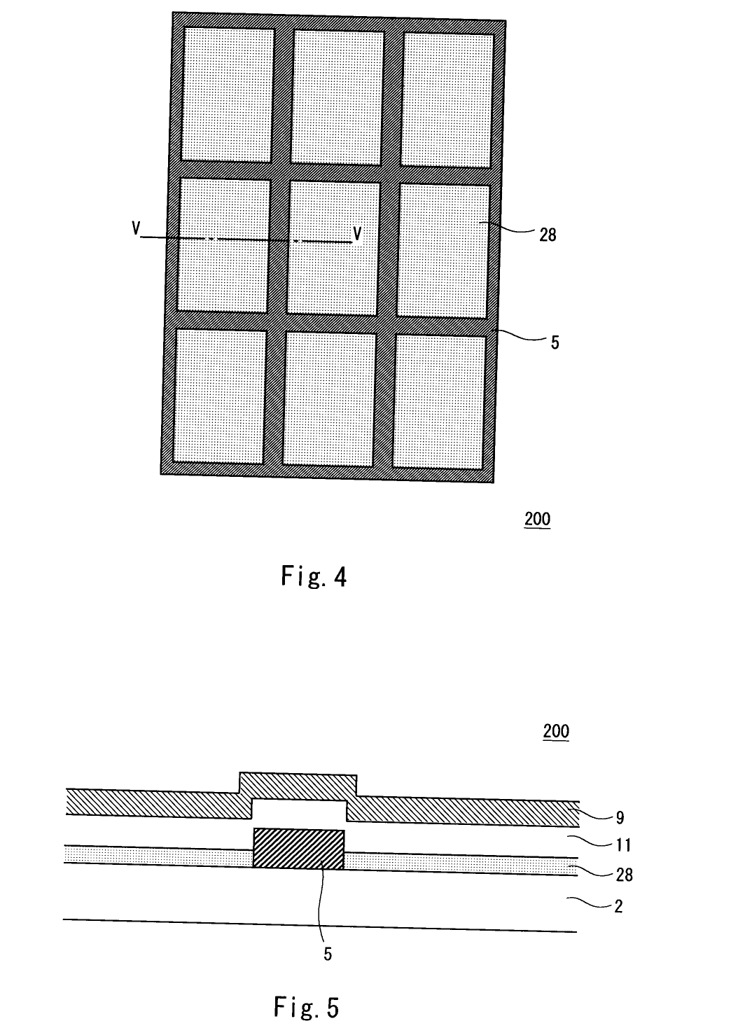

Next, the pixel configuration of the opposing substrate 200 is described hereinafter with reference to FIGS. 4 and 5. FIG. 4 is a plan view showing the configuration of a part of the opposing substrate 200. FIG. 5 is a cross-section diagram taken along the line V-V of FIG. 4. In the explanation hereinbelow, the opposing substrate 200 is assumed be a color filter substrate. Over the opposing substrate 200, a black matrix 5 is formed in lattice. The black matrix 5 is formed by a light-blocking resin film or chromium metal film etc. A RGB colored layer 28 is formed between the black matrix 5. The colored layer 28 is placed corresponding to the pixel electrode 24. Furthermore, the black matrix 5 is placed corresponding to the source lines 25 and gate lines 26. Over the black matrix 5 and colored layer 28, an opposing electrode 11 is formed. The opposing electrode 11 is formed by a transparent conductive film such as ITO. The opposing electrode 11 is formed almost the entire surface of the opposing substrate 200 so as to cover the black matrix 5 and colored layer 28. Note that the opposing substrate 200 is not limited to the color filter substrate.

The alignment film 9 is formed over the opposing electrode 11. The alignment film 9 is formed in the liquid crystal filled area 102. Accordingly the alignment 9 is not formed in the end part of each element segment and the opposing electrodes 11 are exposed. Accordingly the opposing electrode 11 is exposed in the end part of the opposing substrates 200. For the alignment film 9 as with the TFT array substrate 100, a resin film made of polyimide or the like can be used. Furthermore, the alignment film 9 is rubbed in a predetermined direction. Note that over the opposing electrodes 11, a hydrophobic film having a predetermined contact angle to water is formed. The configuration of the hydrophobic film is described later in detail. Meantime, the hydrophobic film can be formed after forming the opposing electrodes 11 and before forming the alignment film 9. Alternatively, the hydrophobic film may be formed after forming the alignment film 9 and before bonding the TFT array substrate with opposing substrate 200.

Then, after completing the rubbing process for the alignment films 9 and 10, the mother substrate 1 is bonded with the mother substrate 2. Accordingly, firstly a seal material is formed to the mother substrate 1 or 2. The seal material is formed to each of the 12 element segments 101. Then the seal material is placed to shape a frame, surrounding the liquid crystal filled area 102. Also, a liquid crystal filling opening is formed to a part of the seal material. Next, the mother substrate 1 and 2 are aligned and placed opposite each other. Here, the alignment films 9 and 10 are placed to face each other. Then both of the substrates are pressed and the seal material is cured. This makes the mother substrates 1 and 2 to be bonded with the seal material interposed therebetween. Note that before bonding, transfer electrodes or the like are formed so that the test line 18 and opposing electrode 11 are connected. For the transfer electrodes, silver paste can be used for example. Moreover, before bonding, a spacer may be placed to keep the cell gap.

Then by cutting the bonded mother substrates 1 and 2 along the cutting lines 104 in horizontal direction shown in FIGS. 1 and 3, stick substrates are formed. In this example, 3 stick substrates having 4 element segments 101 arranged in one line are formed. Liquid crystal can be filled to the liquid crystal filled areas 102 of the 4 element segments 101 at the same time. This improves the productivity. The liquid crystal can be filled by a vacuum filling method, for example. After filling the liquid crystal, a resin is coated to the crystal liquid filling opening to seal. This enables to fill the liquid crystal in the space formed by the opposing substrates 200, TFT array substrates 100 and seal material.

The stick substrate is formed in this way. The stick substrate here indicates a pair of laminated substrates obtained by cutting and dividing the mother substrates 1 and 2 after the mother substrates 1 and 2 are bonded. In the stick substrate, the plurality of element segments 101 are arranged in one line. After a test is carried out, the stick substrates are cut. This separates into each element segment 101 and divides into each liquid crystal panel.

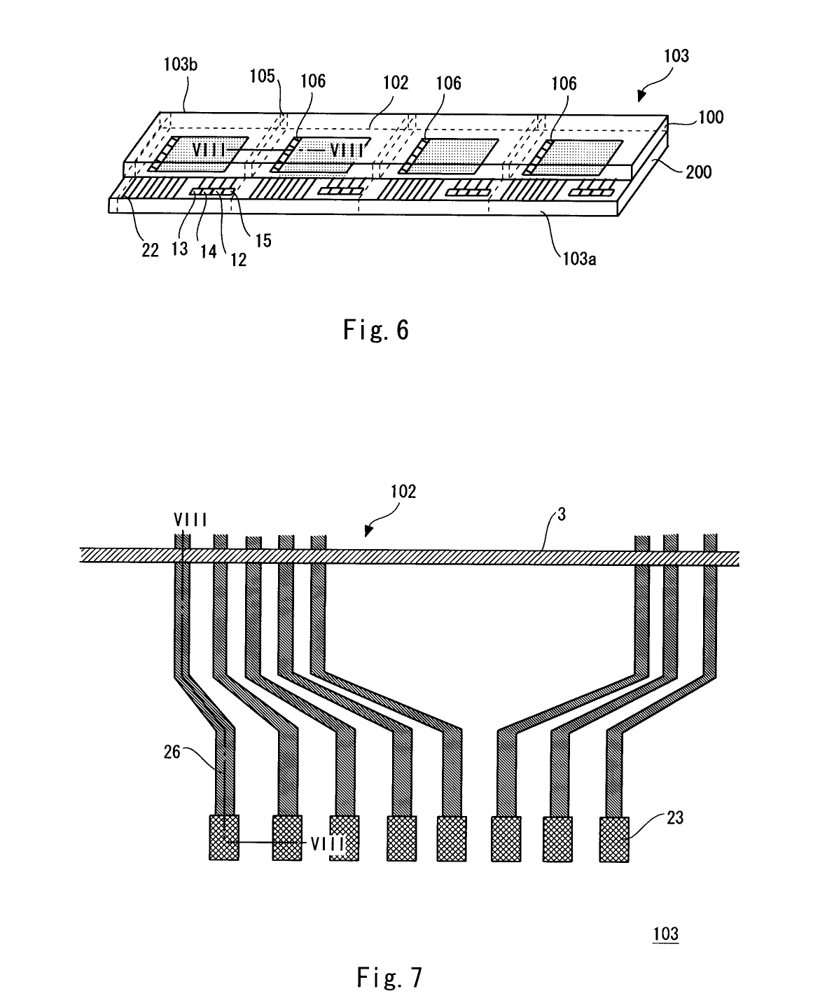

The configuration of the stick substrate is described hereinafter with reference to FIG. 6. FIG. 6 is a perspective view showing the configuration of the stick substrate. Note that FIG. 6 shows the end part side of the stick substrate 103 where the test terminals 12 to 15 and source terminals 22 are provided. The stick substrate 103 includes a stick shaped array substrate 103a and stick shaped opposing substrate 103b. Here, the stick shaped array substrate 103a is placed so that the end part of the stick shaped array substrate 103a runs over the stick shaped opposing substrate 103b. The source terminals 22 and test terminals 12 to 15 are placed to the running over part of the stick shaped array substrate 103a which runs over the stick shaped opposing substrate 103b. More specifically, the source terminals 22 and test terminals 12 to 15 are exposed. The test terminals 12 to 15 and the plurality of source terminals 22 are arranged in almost one line along the end side of the stick shaped array substrate 103a. In a test process for the state of the stick substrate 103, at the state shown in FIG. 6, a test signal is input to the test terminals 12 to 15. Here, a lighting test can be carried out at the same time to the 4 element segments.

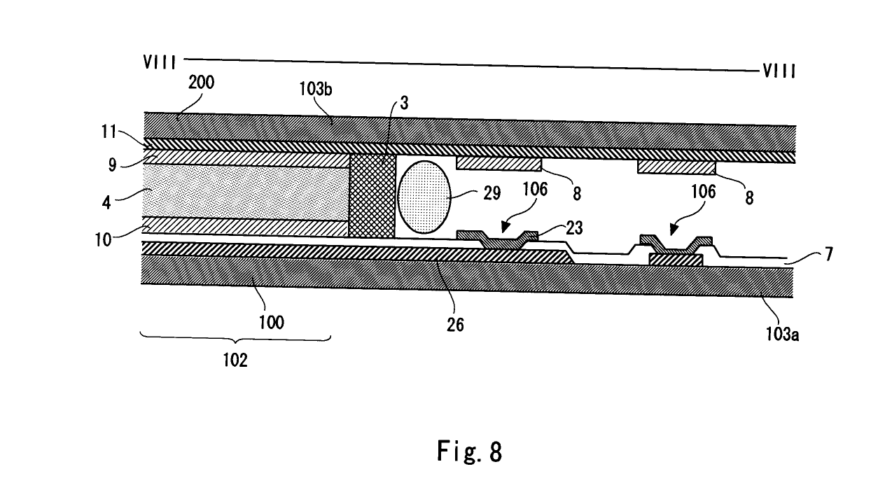

The configuration between the element segments 101 in the stick substrate 103 is described with reference to FIGS. 7 and 8. FIG. 7 shows the configuration of the side of the TFT array substrate 100 along the line VIII-VIII of FIG. 6. FIG. 8 is a cross-section diagram taken along the line VIII-VIII of FIG. 6. Note that the line VIII-VIII is a line along with the gate line 26.

As shown in FIG. 7, a seal material 3 is formed between the element segments 101 of the stick substrate 103. The plurality of gate lines 26 are placed to intersect the seal material 3. Furthermore, the gate terminals 23 are placed at the end of the gate lines 26. Outside the seal material 3, the plurality of gate terminals 23 are arranged in one line along the direction where the seal material 3 is provided. Note that in FIG. 7, the lower side of the seal material 3 is the area between the element segments 101 and upper side is the liquid crystal filled area 102. Thus at the state of the stick substrate 103, the gate terminals 23 are exposed to the outside air. Note that even outside the liquid crystal filled area 102, the gate lines 26 are covered by the insulating film 7 as shown in FIG. 8. The gate terminals 23 are connected with the gate lines 26 via contact holes provided to the insulating film 7. Therefore, only the gate terminals 23 are exposed to the surface and in the place other than the gate terminals 23, the insulating film 7 is exposed.

As shown in FIG. 8, the stick shaped array substrate 103a and stick shaped opposing substrate 103b are bonded by the seal material 3. Inside the seal material 3 is the liquid crystal filled area 102. In FIG. 8, left side is the liquid crystal filled area 102. In the liquid crystal filled area 102 as described above, the opposing electrode 11 and alignment film 9 are formed sequentially to the stick shaped opposing substrate 103b. Moreover, to the stick shaped array substrate 103a, the gate line 26,insulating film 7 and alignment film 10 are laminated sequentially. Note that the insulating film 7 is for example the abovementioned gate insulating film or interlayer insulating film. A liquid crystal 4 is provided between the alignment films 9 and 10.

Here at the state of the stick substrate 103, the opposing substrate 11 is placed over the gate terminals 23. An area where the gate terminals 23 face the opposing substrate 11 is referred to as a terminal electrode opposing area 106 here. A hydrophobic film 8 is formed to the stick shaped opposing substrate 103b. The hydrophobic film 8 is placed to the terminal electrode opposing area 106. Specifically, the gate terminals 23 face the opposing electrode 11 with the hydrophobic film 8 interposed therebetween. The hydrophobic film 8 has a high contact angle to water. For the hydrophobic film 8, a fluorinated silicone resin may be used for example. More specifically, a commercially available photosensitive resin such as a fluorinated silicon resin or the like for forming a water-repellent film manufactured by Toshiba Silicone Co., Ltd. can be used. Thus a photosensitive resin having hydrophobicity and water-repellency is coated over the mother substrate 2, exposed and developed. This enables to easily form the hydrophobic film 8 having a desired pattern.

A test signal is input from the test terminal 13 to the gate lines 26. Thus the gate terminals 23 connected with the gate lines 26 have a potential corresponding to the test signal. A test signal is also input to the test terminal 14. Accordingly, a test signal is input to the opposing substrate 11 via the test line 18 and transfer electrodes or the like. Thus the opposing electrode 11 also has a potential corresponding to the test signal. The test signals input to the test terminals 14 and 13 are different here. Thus different voltages corresponding to the test signals are applied to the opposing substrate 11 and gate terminals 23. Therefore, a lighting test is carried out to each of the element segments 101 of the stick substrate 103.

In this embodiment as described above, in the terminal electrode opposing area 106, the hydrophobic film 8 is formed to the stick shaped opposing substrate 103b. Thus even when a voltage is applied the opposing electrode 11 and the gate terminals 23 that are exposed to the surface in a test process, corrosion in the gate terminals 23 can be prevented. This enables to prevent generating display failure. To be more specific, even when a water droplet 9 immerses in a cleansing process or by moisture condensation, the hydrophobic film 8 prevents the water droplet 29 from immersing into the terminal electrode opposing area 106. For example, even when the water droplet 29 immerses between the element segments 101, which is between the stick shaped array substrate 103a and stick shaped opposing substrate 103b, the water droplet 29 moves avoiding the hydrophobic film 8 having a high contact angle. Thus the water droplet 29 does not attach to the gate terminals 23. Even when a potential difference is generated between the opposing substrate 11 and gate terminal 23 or between the gate terminals 23, it is possible to prevent from generating an electrochemical reaction. Thus display failure can be prevented from generating. This enables to prevent from reducing display quality.

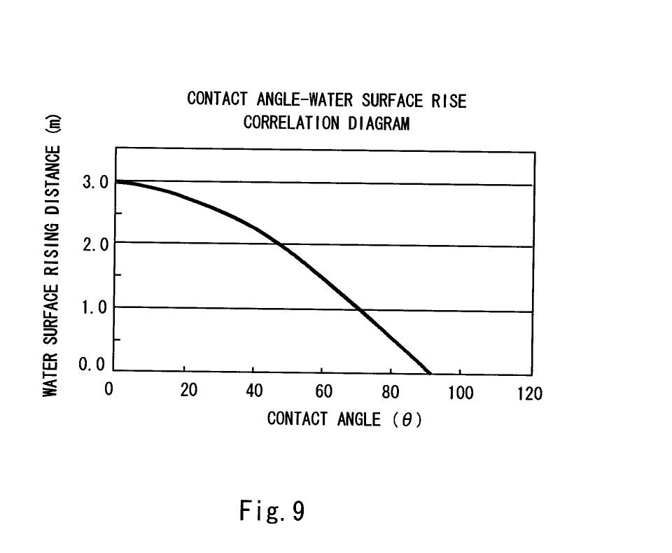

An example of the relationship between the contact angle and a rising distance of water surface due to capillary phenomenon is shown in FIG. 9. According to FIG. 9, as long as the hydrophobic film 8 has a contact angle of 90 degree Celsius or more, no water will immerse due to capillary phenomenon. Thus it is possible to prevent from corrosion caused by water immersing. Note that FIG. 9 shows the result after sufficient time and in fact, only a certain difference in the contact angles between the hydrophobic film 8 and other area is needed. For example for the hydrophobic film 8, a material having a higher contact angle than the opposing electrode 11 can be used.

As described above, in the terminal electrode opposing area 106, the hydrophobic film 8 is provided to the stick shaped opposing substrate 103b. The hydrophobic film 8 is formed to all of the plurality of gate terminals 23. This enables to prevent from corrosion even when a voltage is applied in a test process. Thus it is possible to prevent from deteriorating display quality. As described above, even when a cleansing process is carried out after bonding the mother substrates 1 and 2, it is possible to prevent the water droplet 29 from immersing. For example, the stick substrate 103 can be cleansed. Furthermore, at the state of the stick substrate 103, even when the water droplet 29 immerses between both of the substrates due to capillary phenomenon, the water droplet 29 moves avoiding the hydrophobic film 8. Thus the water droplet 29 does not attach to the gate terminals 23. It is possible to prevent the water droplet 29 from immersing into the terminal electrode opposing area 106. Thus the deterioration of display quality due to electrolytic corrosion can be reduced. In addition, as only the hydrophobic film 8 needs to be formed, the corrosion caused by the electrochemical reaction can be prevented easily.

Then, after completing the test process, the stick substrate 103 is divided and separated into element segments 101. In this example, the stick shaped opposing substrate 103b is cut along the cutting lines 105 shown in FIG. 6. This separates into liquid crystal panels composed of the TFT array substrate 100 and opposing substrate 200. Then a driving circuit and wiring board etc. are connected to the liquid crystal panel. Furthermore, a polarizing film and retardation film or the like are attached to the liquid crystal panel. After that, by placing a backlight, which is a planar light source apparatus, to the back of the liquid crystal panel, a liquid crystal display is completed.

In a cutting process for cutting the stick substrate 103 after the test process, the opposing substrate 200 of the terminal electrode opposing area 106 shown in FIG. 8 is removed. More specifically, the opposing substrate 200 is not provided above the gate terminals 23. Accordingly, the hydrophobic film 8 is separated from the opposing substrate 200. This enables to easily connect a driving circuit to the gate terminals 23.

As described above, according to this embodiment, at the state of the stick substrate 103, the hydrophobic film 8 is placed between the gate terminals 23 and opposing electrode 11. Thus in a test process at the state of the stick substrate 103, even when a potential difference is generated between the gate terminal 23 and opposing electrode 11 or between gate terminals 23, corrosion caused by an electrochemical reaction can be prevented. Further, as a test can be performed at the state of the stick substrate 103, yield can be improved. Furthermore, as a patterning process of the opposing electrodes can be omitted, a liquid crystal display with high display quality can be manufactured at low cost. Thus the productivity can be improved. Moreover, the configuration of this embodiment can be incorporated to a horizontal electric filed liquid crystal display that does not require the opposing electrode for the opposing substrate 200. In such case, corrosion in the gate terminals 23 caused by a potential difference between the gate terminals 23 can be prevented.

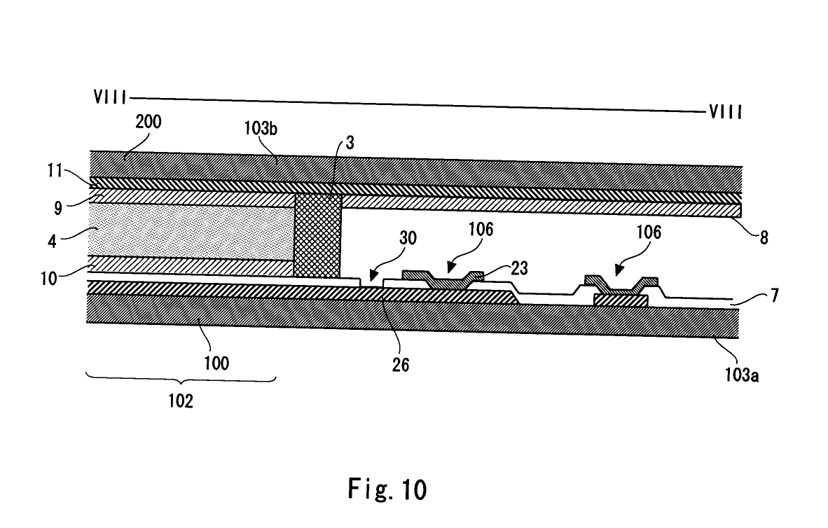

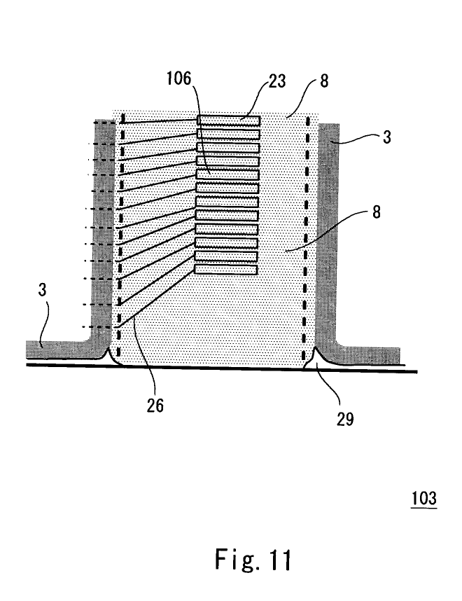

Note that the hydrophobic 8 may at least be formed in the terminal electrode opposing area 106. Thus the location of the hydrophobic 8 is not limited to the one shown in FIG. 8. Here, another configuration of the stick substrate 103 of this embodiment is described with reference to FIGS. 10 and 11. FIG. 10 is a cross-section diagram of the stick substrate 103 taken along the line VIII-VIII. FIG. 11 is a plan view schematically showing the stick substrate 103 having the configuration shown in FIG. 10. In FIGS. 10 and 11, the location of the hydrophobic film 8 is different as compared to the configuration of FIG. 8. As the configuration except the hydrophobic film 8 is same as the configuration described above, the explanation is omitted here.

As shown in FIG. 10, the hydrophobic 8 is provided not only in the terminal electrode opposing area 106 but to the outside. Therefore, the hydrophobic film 8 is formed to all over the outside of the liquid crystal filled area 102. That is, the hydrophobic film 8 is formed all over between the seal material 3 formed to adjacent element segments 101. Thus in the area between the element segments 101, opposing electrode 11 is not exposed. Accordingly, the hydrophobic film 8 is formed over the opposing electrode 11 to almost all over the area outside the seal material 3.

Such hydrophobic film 8 is also formed in the area facing the gate lines 26. That is, the hydrophobic film 8 is formed between the gate lines 26 and opposing electrode 11. Thus, in outside the seal material 3, even when a defect such as a pinhole 30 is created in the insulating film 7 that covers the gate line 26, corrosion caused by the water droplet 29 can be prevented. Specifically, as the hydrophobic film 8 is provided in the portion facing the pinhole 30, the water droplet 29 does not attach to the gate line 26 that is exposed from the pinhole 30. Thus an electrochemical reaction generated when applying a voltage can be prevented and the corrosion in the gate line 26 can be prevented. Note that the hydrophobic film 8 needs not to be provided to all over the element segments 101. For example, the hydrophobic film 8 may be formed in the area facing the gate lines 26. More specifically, the hydrophobic film 8 may be formed in a line formed area where the gate lines 26 are formed outside the seal material 3.

### Second Embodiment

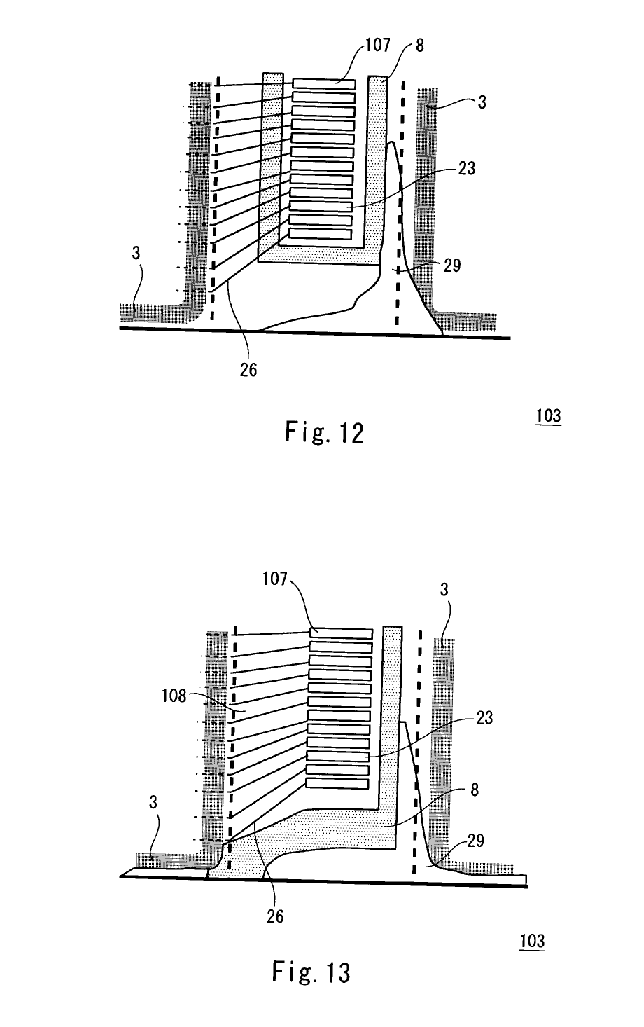

A liquid crystal display of this embodiment is described with reference to FIG. 12. FIG. 12 is a plan view schematically showing the configuration of the stick substrate 103. In FIG. 12 as with FIG. 11, the configuration between the element segments 101 is shown. In this embodiment, the hydrophobic film 8 is provided to the stick shaped array substrate 103a, not to the stick shaped opposing substrate 103b. As the configuration except the hydrophobic film 8 and manufacturing process are same as the first embodiment, the explanation is omitted here.

The hydrophobic film 8 is provided to the surface of the stick shaped array substrate 103a. The area where the plurality of gate terminals 23 are formed is referred to as a terminal formed area 107. The hydrophobic film 8 is formed near the terminal formed area 107. Then the hydrophobic film 8 is formed to surround the terminal formed area 107. Accordingly, the hydrophobic film 8 is placed outside the gate terminals 23. The hydrophobic film 8 is provided over the insulating film 7 for example, and exposed to the surface. Therefore, even when the water droplet 29 immerses between the substrates, the water droplet 29 does not immerse into the terminal formed area 107. As the water droplet 29 does not attach to the gate terminals 23, corrosion of the terminals 23 caused by an electrochemical reaction can be prevented. That is, as the water droplet 29 does not immerse inside the hydrophobic film 8, the corrosion of the gate terminals 23 can be prevented even if a voltage is applied in a test process. Thus, even when the stick substrate 103 is cleansed, it is possible to prevent corrosion.

As for the hydrophobic film 8, a photosensitive fluorinated silicone resin can be used as with the first embodiment. The hydrophobic film 8 may only need to be a material having a higher contact angle than its peripheral parts. For example, the contact angle of the hydrophobic film 8 is higher than that of the surface of the insulating film 7 that covers the gate lines 26. That is, the material may be a material having a higher contact angle than a silicon oxide film or silicon nitride film to be the gate insulating film or interlayer insulating film. The hydrophobic film 8 is formed over the insulating film 7.

In this embodiment, the hydrophobic film 8 is formed to the stick shaped array substrate 103a. Thus, after separating into each element segment 101, the hydrophobic film 8 remains over the TFT array substrates 100. Specifically, in the state of liquid crystal panels, the hydrophobic film 8 is placed outside the gate terminals 23. The hydrophobic film 8 is formed to surround the terminal formed area 107 of the liquid crystal panel. This enables to prevent from corrosion caused by an electrochemical reaction. Furthermore, as a resin or the like is not formed to the surface of the gate terminals 23, a connection with the driving circuit can easily made with low electric resistance. Then, an ACF or the like is provided over the gate terminals 23 surrounded by the hydrophobic film 8 so as to connect the driving circuit. This enables to easily mount the driving circuit.

Note that the location of the hydrophobic film 8 is not limited to be formed to surround the terminal formed area 107. For example, the hydrophobic film 8 may only be formed outside the terminal formed area 107. Another configuration in which the location of the hydrophobic film 8 is changed is described hereinafter with reference to FIG. 13. FIG. 13 is a plan view schematically showing the configuration of the stick substrate 103. Also in the configuration shown in FIG. 13, the hydrophobic film 8 is formed to the stick shaped array substrate 103a. However, the hydrophobic film 8 is not formed to surround the terminal formed area 107.

Specifically, the hydrophobic film 8 is formed outside and both sides the terminal formed area 107. Furthermore, the hydrophobic film 8 is extended to the seal material 3. More specifically, the seal material 3 and hydrophobic film 8 surround the terminal formed area 107. This enables to prevent the water droplet 29 from attaching to the gate terminals 23 even when the water droplet 29 is immersed between the substrates. Thus it is possible to suppress from deteriorating display quality caused by electrolytic corrosion.

Here, the area where the plurality of gate lines 26 are formed is referred to as a line formed area 108. The seal material 3 and hydrophobic film 8 surround the line formed area 108 This enables to prevent the water droplet 29 from immersing over the gate lines 26. That is, the water droplet 29 immersed between the substrates moves only outside the area formed by the hydrophobic film 8 and seal material 3. The water droplet 29 does not immerse into the line formed area 108. As shown in FIG. 10, this enables to prevent from corrosion of the gate lines 26 even when the pinhole 30 is created in the insulating film 7 that covers the gate lines 26. It is possible to prevent from generating a change in electric resistance and suppresses from deteriorating display quality caused by electrolytic corrosion. Thus the display quality can be improved.

In order to form the hydrophobic film 8 over the TFT array substrates 100, the hydrophobic film 8 may be provided near the gate terminals 23. Moreover, the hydrophobic film 8 is placed outside the gate terminals 23, which is closer the end of the TFT array substrate 100 than the gate terminals 23. In such case, the gate terminals 23 are placed between the seal material 3 and hydrophobic film 8. This enables to prevent water from immersing externally. Furthermore, by surrounding the terminal formed area 107 by the hydrophobic film 8, it is possible to assure preventing a water droplet from attaching to the gate terminals 23. Alternatively, the terminal formed area 107 maybe surrounded by the hydrophobic film 8 and seal material 3. This assures to prevent the water droplet 29 from attaching to the gate terminals 23. In such case, the line formed area 108, which is outside the seal material 3, is surrounded by the hydrophobic film 8 and seal material 3. This enables to prevent from corrosion of the gate lines 26.

Although that in the first and second embodiment, the hydrophobic film 8 is explained for preventing corrosion of the gate terminals 23, the present invention is not limited to this. For example, the hydrophobic film 8 may be formed to the source terminals 22 or test terminals 12 to 15. Specifically, the hydrophobic film 8 may be provided to the input terminals configured to input signals from outside. Specifically, at the state of the stick substrate 103, the hydrophobic film 8 may be provided to the input terminal exposed outside the liquid crystal area 102 and facing the opposing electrode 11. This enables to prevent from generating corrosion in a test process even when a water droplet immerses between the substrates. Thus it is possible to prevent from deteriorating display quality. In addition, the first and second embodiments may be combined. Specifically, a hydrophobic film may be formed to both of the stick shaped array substrates 103a and 103b.

Also in the first and second embodiments, the active matrix liquid crystal display having TFT array substrates is explained, but the present invention is not limited to this. For example it may be a passive matrix liquid crystal display. Moreover, it may be a display apparatus using display materials other than liquid crystals such as an electronic paper. Furthermore in the above explanation, the liquid crystal filling process and test process are carried out after cutting the mother substrates 1 and 2, however it is not limited to this. For example if the element segments 101 are arranged in one line for the mother substrates 1 and 2, the liquid crystal filling process and test process can be carried out before cutting the mother substrates 1 and 2. Specifically, the test process may only need be carried out before separating into each element segment to form liquid crystal panels.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A panel substrate comprising:
a first mother substrate having a plurality of array substrates;
a second mother substrate having a plurality of opposing substrates opposing to the array substrates;
a seal material for bonding the array substrates and the opposing substrates;
a display material provided in a space formed by the array substrates, the opposing substrates and the seal material;
a line provided to the first mother substrate;
an input terminal formed outside a display material filled area in the array substrate for inputting a signal to the line, the display material filled area having the display material being filled therein; and
a hydrophobic film formed over the second mother substrate and placed in an opposing area having the input terminal facing the opposing substrate.

2. The panel substrate according to claim 1, wherein the hydrophobic film is also formed in a line formed area having the line formed outside the seal material.

3. A display apparatus comprising:
an array substrate;
an opposing substrate placed opposing the array substrate;
a seal material for bonding the array substrate and the opposing substrate;
a display material provided in a space formed by the array substrate, the opposing substrate and the seal material;
a line provided over the array substrate;
an input terminal formed outside the seal material of the array substrate for inputting a signal in the line; and
a hydrophobic film formed over the array substrate and provided closer to the array substrate end than the input terminal.

4. The display apparatus according to claim 3, wherein the hydrophobic film is placed to surround a terminal formed area having the input terminal formed therein.

5. The display apparatus according to claim 3, wherein the hydrophobic film and the seal material surround the terminal formed area having the input terminal formed therein.

6. The display apparatus according to claim 5, wherein a line formed area having the line formed therein outside the seal material is surrounded by the hydrophobic film and the seal material.

7. A method of manufacturing a display apparatus having an array substrate with an input terminal for inputting a signal to a line and an opposing substrate from a first mother substrate having a plurality of the array substrates and a second mother substrate having a plurality of opposing substrates, the method comprising:
forming a hydrophobic film near the input terminal over the first mother substrate;
bonding the first mother substrate with the second mother substrate with a seal material interposed therebetween so that the hydrophobic film formed to the first mother substrate faces the opposing substrate;
filling a display material in a space formed by the seal material, the opposing substrate and the array substrate;
inputting a signal to the line in order to perform a test process at a state in which the hydrophobic film faces the input terminal outside a display material filled area having the display material filled therein; and
dividing into a display panel having one opposing substrate and one array substrate after the test process.

8. A method of manufacturing a display apparatus having an array substrate with an input terminal for inputting a signal to a line and an opposing substrate from a first mother substrate having a plurality of the array substrates and a second mother substrate having a plurality of opposing substrates, the method comprising:
forming a hydrophobic film over the opposing substrate of the second mother substrate;
bonding the first mother substrate with the second mother substrate with a seal material interposed therebetween so that the hydrophobic film formed to the second mother substrate faces the input terminal;
filling a display material in a space formed by the seal material, the opposing substrate and the array substrate;
inputting a signal to the line in order to perform a test process at a state in which the hydrophobic film faces the input terminal outside a display material filled area having the display material filled therein; and
dividing into a display panel having one opposing substrate and one array substrate after the test process.

9. The method according to claim 7, further comprising:
cutting the bonded first and the second mother substrate and forming a stick substrate having a plurality of the opposing substrates and array substrates,
wherein the test process is performed after cutting into the stick substrate.

10. The method according to claim 8, further comprising:
cutting the bonded first and second mother substrates and forming a stick substrate having a plurality of the opposing substrates and the array substrates;
wherein the test process is performed after cutting into the stick substrate.

11. The method according to claim 7, wherein the hydrophobic film is formed by a photosensitive resin film with hydrophobicity.

12. The method according to claim 8, wherein the hydrophobic film is formed by a photosensitive resin film with hydrophobicity.

13. The method according to claim 9, wherein the hydrophobic film is formed by a photosensitive resin film with hydrophobicity.

14. The method according to claim 10, wherein the hydrophobic film is formed by a photosensitive resin film with hydrophobicity.
